(19) United States
(12) Patent Application Publication
(10) Pub. No.: US 2018/0323253 A1
(43) Pub. Date: Nov. 8, 2018

(54) SEMICONDUCTOR DEVICES WITH THROUGH-SUBSTRATE COILS FOR WIRELESS SIGNAL AND POWER COUPLING

(71) Applicant: Micron Technology, Inc., Boise, ID (US)

(72) Inventor: Kyle K. Kirby, Eagle, ID (US)

(21) Appl. No.: 15/584,310

(22) Filed: May 2, 2017

(51) Int. Cl. H01L 49/02; H01L 23/522; H01L 23/64

(52) U.S. Cl. CPC H01L 28/10; H01L 2223/64; H01L 23/645; H01L 23/5227

(57) ABSTRACT

A semiconductor device comprising a substrate and a substantially spiral-shaped conductor is provided. The substantially spiral-shaped conductor extends substantially into the substrate and has a spiral axis substantially perpendicular to a surface of the substrate. The substantially spiral-shaped conductor can be configured to be wirelessly coupled to another substantially spiral-shaped conductor in another semiconductor device.

### CROSS-REFERENCE TO RELATED APPLICATION(S)

This application contains subject matter related to a concurrently-filed U.S. Patent Application by Kyle K. Kirby, entitled “SEMICONDUCTOR DEVICES WITH BACK-SIDE COILS FOR WIRELESS SIGNAL AND POWER COUPLING.” The related application, of which the disclosure is incorporated by reference herein, is assigned to Micron Technology, Inc., and is identified by attorney docket number 10829-9206.US00.

This application contains subject matter related to a concurrently-filed U.S. Patent Application by Kyle K. Kirby, entitled “INDUCTORS WITH THROUGH-SUBSTRATE VIA CORES.” The related application, of which the disclosure is incorporated by reference herein, is assigned to Micron Technology, Inc., and is identified by attorney docket number 10829-9208.US00.

This application contains subject matter related to a concurrently-filed U.S. Patent Application by Kyle K. Kirby, entitled “MULTI-DIE INDUCTORS WITH COUPLED THROUGH-SUBSTRATE VIA CORES.” The related application, of which the disclosure is incorporated by reference herein, is assigned to Micron Technology, Inc., and is identified by attorney docket number 10829-9220.US00.

This application contains subject matter related to a concurrently-filed U.S. Patent Application by Kyle K. Kirby, entitled “3D INTERCONNECT MULTI-DIE INDUCTORS WITH THROUGH-SUBSTRATE VIA CORES.” The related application, of which the disclosure is incorporated by reference herein, is assigned to Micron Technology, Inc., and is identified by attorney docket number 10829-9221.US00.

### TECHNICAL FIELD

The present disclosure generally relates to semiconductor devices, and more particularly relates to semiconductor devices with through-substrate coils for wireless signal and power coupling.

### BACKGROUND

Semiconductor devices are often provided in packages with multiple connected dies, in which circuit elements of the various dies are connected in various ways. For example, a multi-die package may utilize wire bonds from each die to an interposer to provide connection between elements in different die. Although direct electrical connections between circuit elements in different die are sometimes desirable, in other cases it may be desirable to connect elements from disparate die wirelessly (e.g., via inductive coupling, capacitive coupling, or the like). To facilitate such a wireless communication between circuit elements, planar coils can be provided among the circuit elements, such that adjacent die in a multi-die stack can have proximate coils that communicate wirelessly.

One approach to providing coils for wireless communication involves packaging two die in a face-to-face arrangement, such that respective pairs of wireless coils in the active layer of each die are placed in close proximity. This approach is illustrated in FIG. 1, which shows two such die 101 and 102 with front-side coils, such as coils 111 and 112, being placed in proximity with one another. A face-to-face arrangement of die limits the number of die that can be packaged together, however, so other approaches for larger numbers of die have been attempted.

Another approach to providing coils for wireless communication involves thinning the die in a semiconductor package sufficiently so that the coils on the front side of each die in the package are separated by only about the height of the thinned die when packaged in a front-to-back arrangement. This approach is illustrated in FIG. 2, in which three thinned dies 201, 202 and 203 are disposed in a front-to-back arrangement, such that the distance between coils in adjacent tides, such as between coils 211 and 212 or coils 212 and 213, is small enough to permit wireless communication. Although this approach allows for packages with more than two dies, the distance between coils is much larger than in the arrangement of FIG. 1, and accordingly the size of the coils must be increased to compensate, which can dramatically increase the cost of the dies in the package. Accordingly, there is a need for other approaches to providing semiconductor devices with coils for wireless communication that permit more than two dies to be stacked without dramatically increasing the size of the coils.

### BRIEF DESCRIPTION OF THE DRAWINGS

FIG. 1 is a simplified perspective view of a multi-die semiconductor device with front-side coils for wireless coupling.

FIG. 2 is a simplified perspective view of a multi-die semiconductor device with front-side coils for wireless coupling.

FIGS. 3A and 3B are simplified perspective and cross-sectional views of a semiconductor device with a through-substrate coil for wireless communication in accordance with an embodiment of the present technology.

FIG. 3C is a simplified perspective view of a through-substrate coil in accordance with an embodiment of the present technology.

FIG. 4 is a simplified perspective view of a semiconductor device with a through-substrate coil for wireless communication in accordance with an embodiment of the present technology.

FIG. 5 is a simplified cross-sectional view of a semiconductor device with a through-substrate coil for wireless communication in accordance with an embodiment of the present technology.

FIG. 6 is a simplified cross-sectional view of a multi-die semiconductor device with a through-substrate coil for wireless communication in accordance with an embodiment of the present technology.

FIG. 7 is a simplified cross-sectional view of a multi-die semiconductor device with through-substrate coils for wireless communication in accordance with an embodiment of the present technology.

FIG. 8 is a simplified perspective view of a through-substrate coil in accordance with an embodiment of the present technology.

FIG. 9 is a flow chart illustrating a method for forming a semiconductor device with a through-substrate coil in accordance with an embodiment of the present technology.

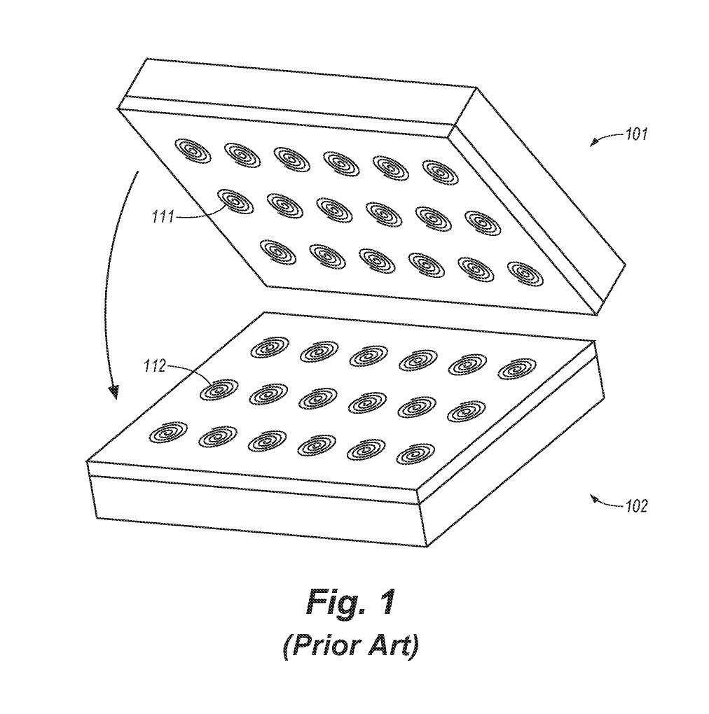

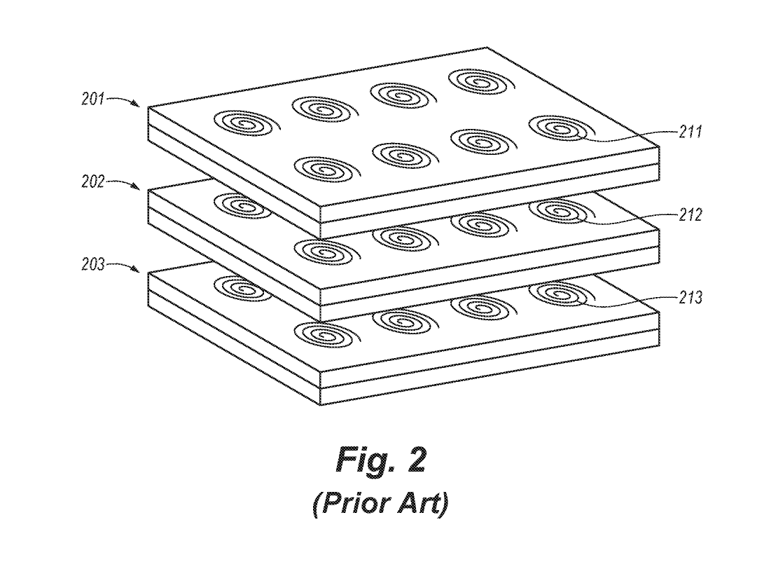

### DETAILED DESCRIPTION

In the following description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with semiconductor devices are not shown, or are not described in detail, to avoid obscuring other aspects of the technology. In general, it should be understood that various other devices, systems, and methods in addition to those specific embodiments disclosed herein may be within the scope of the present technology.

As discussed above, semiconductor devices are continually designed with ever greater needs wireless communication between dies in a semiconductor package. Accordingly, several embodiments of semiconductor devices in accordance with the present technology can provide through-substrate coils that enable wireless communication to adjacent dies in a front-to-back arrangement while only consuming a small area.

Several embodiments of the present technology are directed to semiconductor devices, systems including semiconductor devices, and methods of making and operating semiconductor devices. In one embodiment, a semiconductor device comprises a substrate and a substantially spiral-shaped conductor. The substantially spiral-shaped conductor extends substantially into the substrate and has a spiral axis substantially perpendicular to a surface of the substrate. The substantially spiral-shaped conductor can be configured to be wirelessly coupled to another substantially spiral-shaped conductor in another semiconductor device.

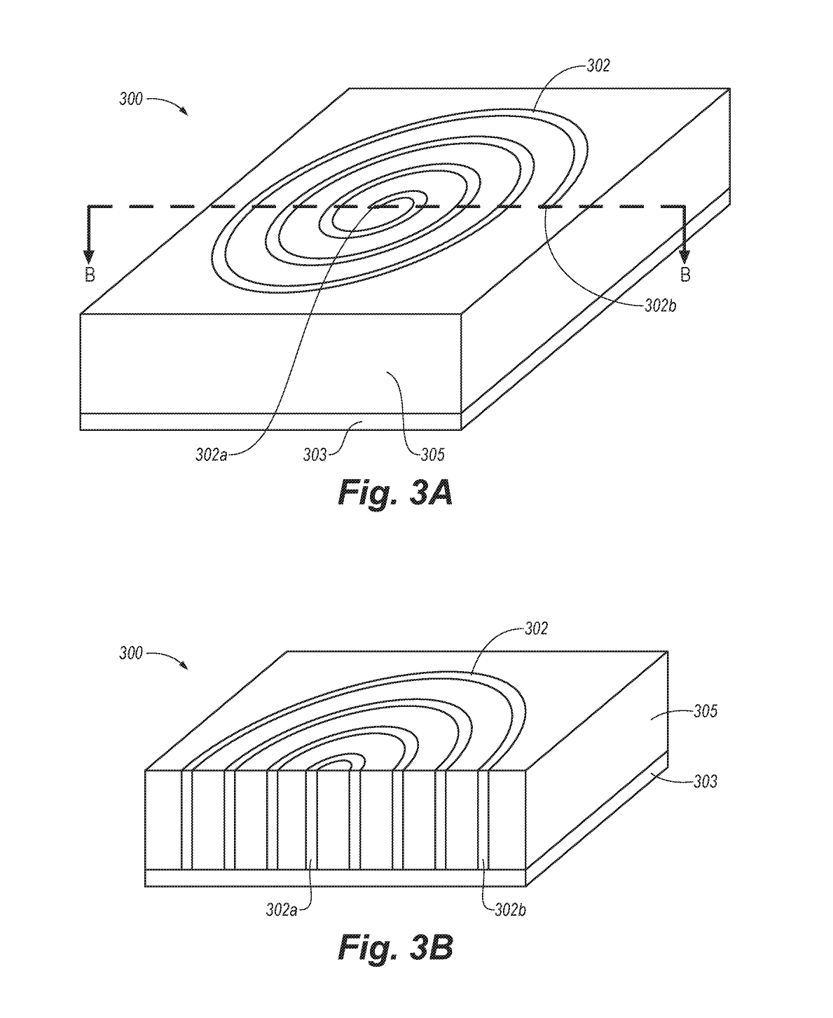

For example, FIGS. 3A and 3B illustrate a semiconductor device with a through-substrate coil for wireless communication in accordance with an embodiment of the present technology. FIG. 3A is a simplified perspective cut-away view of the device 300 showing the uppermost portion of the through-substrate coil 302 (“coil 302”). The coil 302 is formed by a conductor (e.g., a plated conductive material filling a substantially spiral-shaped trench) connecting a first end 302a of the coil 302 to a second end 302b of the coil 302 along a substantially spiral-shaped path. The coil 302 extends substantially into the substrate 305 (e.g., extending downward from a top surface of the substrate 305). As can be seen with reference to FIG. 3A, the coil 302 includes about three and one-half turns (e.g., the spiral-shaped path rotates around its spiral axis, which is perpendicular to a surface of the substrate 305, through about 1260°). In accordance with one embodiment, the planar width of the conductor used to form the coil 302 can be between about 15 and 75 μm, while the spacing between adjacent turns of the conductive trace can be greater than about 50 μm.

Referring to FIG. 3B, the device 300 is shown in cross-section along the section line B-B in FIG. 3A. As can be seen with reference to FIG. 3B, the coil 302 is formed by a conductor with a high aspect ratio extending substantially into the substrate 305. The device 300 also includes a lower layer 303 of insulating material on the back side of the device 300 to insulate the turns of the coil 302 from other devices.

According to one embodiment of the present technology, the coil 302 can include any one of a number of conductive materials compatible with standard semiconductor metallization processes, including copper, gold, tungsten, or alloys thereof. The substrate 305 can likewise include any one of a number of substrate materials suitable for semiconductor processing methods, including silicon, glass, gallium arsenide, gallium nitride, organic laminates, and the like. Additionally, integrated circuitry for memory, controllers, processers and the like can be formed on and/or in the substrate 305.

The coil 302 can be made by etching a high-aspect-ratio substantially spiral-shaped trench into the substrate 305 and filling it with one or more materials in one or more deposition and/or plating steps. The coil 302 can include a bulk material with desirable conductive properties (e.g., copper, gold, tungsten, or alloys thereof), or can include multiple discrete layers, only some of which are conductive, in accordance with an embodiment of the present technology. For example, following a high-aspect ratio etch and a deposition of insulator, the coil 302 can be provided in a single metallization step filling in the insulated substantially spiral-shaped trench with a conductive material. In another embodiment, the coil 302 can be formed in multiple steps to provide layers of different materials. After forming the coil 302 to a desired depth (e.g., about an eventual thickness of the substrate 305), the backside of the substrate can be etched or ground to expose the lowermost portions of the coil 302, to improve wireless coupling to another coil located in another die over which the device 300 is disposed. For example, the substrate 305 can be a thinned silicon wafer of between about 10 and 200 μm thickness, and the coil 302 can extend through the substrate 305, such that the lowermost portions of the coil 302 can be exposed before being covered by the lower layer 303 of insulating material. Accordingly, unlike other circuit elements that are additively constructed on the front or back side of the substrate 305, the coil 302 extends substantially into the substrate 305, enhancing wireless coupling between the coil 302 and another coil located in a die over which the device 300 is disposed.

FIG. 3C is another perspective view of the through-substrate coil 302 of the device 300, in accordance with one embodiment of the present technology. For more easily illustrating the substantially spiral shape of the coil 302 set forth in FIG. 3C, the substrate, insulating materials, and other details of the device 300 in which the coil 302 is disposed have been eliminated from the illustration. The coil 302 is connected at its opposite ends to two vias 308a and 308b, which provide connectivity to the two leads 306a and 306b, respectively.

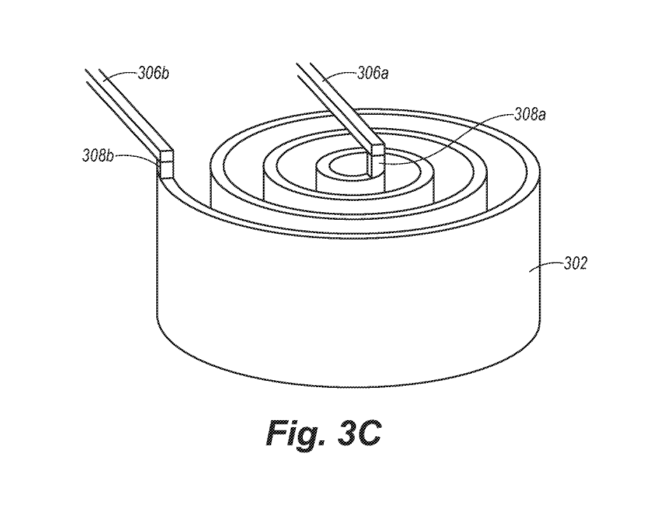

In accordance with another embodiment, the substrate material in which a through-substrate coil is disposed need not be thinned so much that lower portions of the coil are exposed. For example, FIG. 4 illustrates a semiconductor device 400 with a through-substrate coil 402 (“coil 402”) that extends only partway through the substrate 405 of the device 400. In this regard, the coil 402 can be provided to a depth more than halfway through the substrate 405 either by etching a substantially spiral-shaped trench more than half the depth of the substrate 405 before thinning the substrate 405, or alternatively by thinning the substrate 405 after depositing the coil 402 until the substrate 405 is less than twice as thick as the height of the coil 402. Although providing a through-substrate coil that has a height of more than half the thickness of the substrate in which it is disposed can greatly improve the wireless coupling of the through-substrate coil so provided with another coil located in a lower die, embodiments of the present technology can provide through-substrate coils with other heights that can provide a desirable balance between wireless performance and manufacturing cost and complexity. For example, through-substrate coils that extend one-third, two-thirds, one-fourth, one-tenth, or any other fractional part of the way through a substrate can be provided.

Although in the examples of FIGS. 3A through 3C and FIG. 4 the illustrated coils include about three and one-half turns, in other embodiments, the number of turns of a coil can vary. For example, the efficiency of the inductive coupling between two spiral conductors (e.g., coils) can depend upon a number of turns of the coils, such that increasing the number of turns can permit more efficient wireless communication between the two coils (e.g., thereby increasing the distance at which coupled coils can communicate). As will be readily understood by one skilled in the art, however, increasing the number of turns will generally (e.g., where reduction in the size and spacing of the traces is not feasible) increase the area consumed by a coil, such that the number of turns can be for a coil may be selected based upon a desired balance among coil spacing, wireless communication efficiency and circuit area.

By configuring a substantially spiral-shaped conductor to extend into a substrate, embodiments of the present invention permit wireless communication with high efficiency between devices in a stack of dies oriented front-to-back. A coil that extends substantially into (or all the way through) the substrate of one die can be located a shorter distance from a coil in a lower device (either a front-side coil formed on a substrate, or another through-substrate coil) than if the coil did not extend into (or through) the substrate. This smaller coil spacing can provide higher coupling efficiency between the coils, which can in turn permit coils that consume less die area to achieve the same level of performance of larger coils with greater coil spacing.

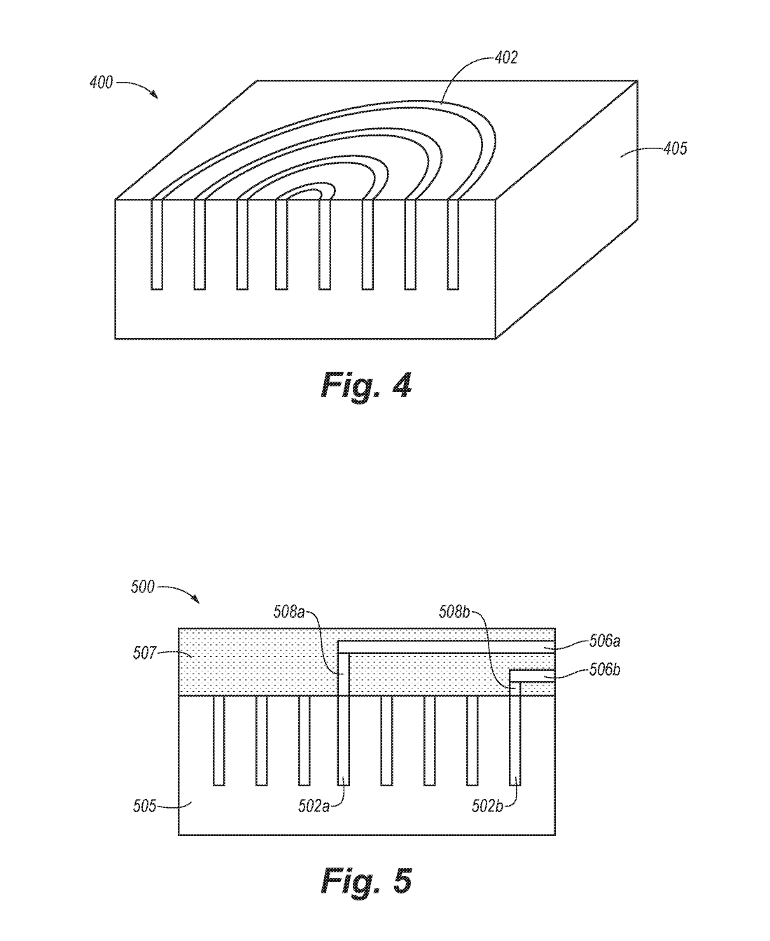

FIG. 5 illustrates a semiconductor device 500 with a through-substrate coil 502 (“coil 502”) in accordance with another embodiment of the present technology. The coil 502 extends substantially into, but not completely through, a substrate 505 of the device 500. The device also includes an upper layer 507 of insulating material in which leads 506a and 506b are disposed. The coil 502 can be connected to other circuit elements (not shown) in the upper layer 507 of insulating material by the leads 506a and 506b. The leads 506a and 506b can be connected to respective ends of the coil 502 by two vias 508a and 508b.

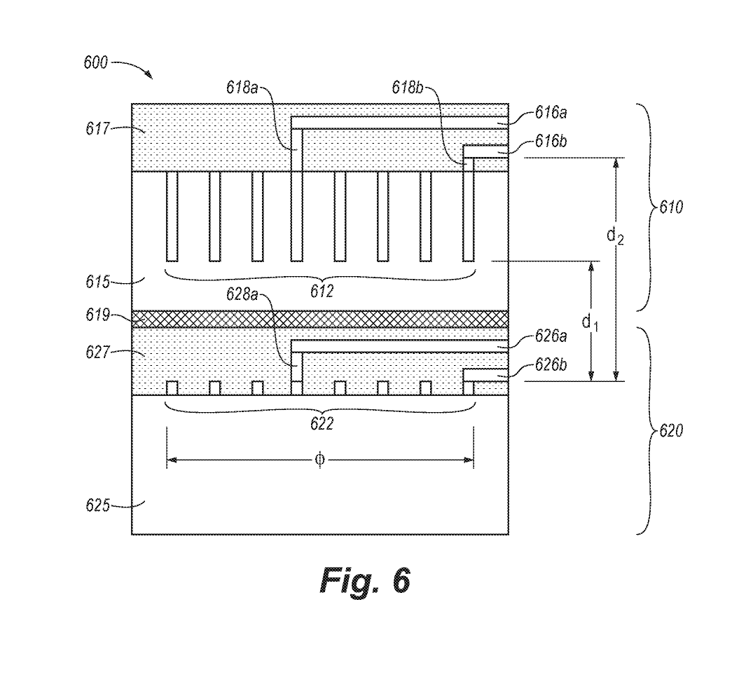

As set forth above, a benefit of providing a semiconductor device with a through-substrate for wireless communication is that packages of more than two die can be configured to wirelessly communicate, even when stacked in a front-to-back configuration. For example, FIG. 6 is a simplified cross-sectional view of a multi-die semiconductor device 600 with through-substrate coils in accordance with an embodiment of the present technology. The device 600 includes a first die 610 having a first substrate 615 and a through-substrate coil 612 (“coil 612”) extending substantially into the first substrate 615. The coil 612 is formed by a conductor (e.g., a plated conductive material filling a substantially spiral-shaped trench) connecting a first end of the coil 612 to a second end of the coil 612 along a substantially spiral-shaped path. As can be seen with reference to FIG. 6, the coil 612 includes about three and one-half turns (e.g., the spiral-shaped path rotates around its spiral axis through about 1260°). The coil 612 can be connected to other circuit elements (not shown) in a first layer 617 of insulating material on the front side of the first die 610 by two leads 616a and 616b. The leads 616a and 616b can be connected to respective ends of the coil 612 by two vias 618a and 618b.

The device further includes a second die 620 having a second substrate 625 and a substantially spiral-shaped planar coil 622 (“coil 622”) disposed in a second layer 627 of insulating material over the second substrate 625. The coil 622 is formed by a conductor (e.g., a conductive trace) connecting a first end of the coil 622 to a second end of the coil 622 along a substantially spiral-shaped path. As can be seen with reference to FIG. 6, the coil 622 also includes about three and one-half turns (e.g., the spiral-shaped path rotates around its spiral axis through about 1260°). The coil 622 can be connected to other circuit elements (not shown) in the second layer 617 of insulating material on the front side of the second die 620 by leads 626a and 626b. The lead 626a can be connected to the center of the coil 622 by a via 628a.

The first die 610 and the second die 620 are stacked front-to-back (e.g., the back side of the first die 610 is facing the front side of the second die 620). The device 600 may optionally include a die attach material 619 (e.g., a die attach film) between the first and second dies 610 and 620. As can be seen with reference to FIG. 6, the distance d₁ between the through-substrate coil 612 of the first die 610 and the coil 622 of the second die 620 is a shorter distance than it would be if the through-substrate coil 612 did not extend into the first substrate 615. For example, the distance d₁ may be between about 5 and 50 μm. According to one embodiment, the distance d₁ between the two wirelessly communicating coils 612 and 622 is much less (e.g., about at least an order of magnitude less) than the area spanned by the two coils 612 and 622 (e.g., the diameter ø of the two coils 612 and 622). For example, in the example of FIG. 6, the diameter ø of the two coils 612 and 622 can be between about 80 and 600 μm. Moreover, the distance d₁ between the two wirelessly communicating coils 612 and 622 is less than (e.g., about half of) the distance d₂ between the coil 622 of the second die 620 and elements on the front side of the first die 610 (e.g., where a front-side coil would have to have been disposed in the absence of the through-substrate coil 612). For example, in the embodiment illustrated in FIG. 6 in which the first die 610 is a thinned silicon wafer, the distance d₂ can be between about 10 and 250 μm.

Although in the example of FIG. 6 the through-substrate coil 612 of the first die 610 and the coil 622 of the second die 620 have been illustrated as having the same diameter ø, in other embodiments wirelessly communicating coils in adjacent die (e.g., coupled front-side and through-substrate coils) need not be the same size (e.g., or shape). For example, a through-substrate coil on a first die can be any size, including between about 80 and 600 μm, and a coil (either a planar front-side coil or a through-substrate coil) on a second die (e.g., wirelessly coupled to the through-substrate coil of the first die) can be a different size selected from the same range. Although matching coil sizes in wirelessly communicating coils can provide the most efficient use of space and least material cost, in some embodiments space constraints on one side may make it desirable to have coils of different sizes. This can facilitate easier alignment or provide slightly better coupling without increasing the size of the corresponding front-side coil.

In accordance with one aspect of the present technology, closely-spaced coils, such as coils 612 and 622, can be configured to wirelessly communicate over near-field distances (e.g., distances less than about three times the diameter ø of the coils, in which the near-field components of the electric and magnetic fields oscillate). For example, the through-substrate coil 612 and the front-side coil 622 can communicate wirelessly using inductive coupling, in which one of the coils (e.g., front-side coil 622 of die 620) is configured to induce a magnetic field with a flux perpendicular to and passing through both the coils 612 and 622 in response to a current passing through the front-side coil 622 (e.g., provided by a voltage differential applied across the leads 626a and 626b). By changing the current passing through the front-side coil 622 (e.g., by applying an alternating current, or by repeatedly switching between high and low voltage states), changes can be induced in the magnetic field, which in turn induces a changing current in the through-substrate coil 612 of the first die 610. In this fashion, signals and/or power can be coupled between a circuit comprising the through-substrate coil 612 of the first die 610 and another comprising the front-side coil 622 of the second die 620. Although the wireless communication between the coils 612 and 622 has been described in the foregoing example with reference to inductive coupling, one skilled in the art will readily appreciate that wireless communication between such closely-spaced coils can be accomplished in any one of a number of other ways, including for example by resonant inductive coupling, capacitive coupling, or resonant capacitive coupling.

Although in the example of FIG. 6, the semiconductor device 600 has been illustrated having a pair of wirelessly communicating coils 612 and 622 having the same number of turns (e.g., three and one-half turns), embodiments of the present technology can provide semiconductor devices with wirelessly communicating coils having different numbers of turns. As will be readily understood by one skilled in the art, providing one coil in a pair of inductively-coupled coils with more turns than the other allows the pair of coupled coils to be operated as a step-up or step-down transformer. For example, the application of a first changing current (e.g., 6V of alternating current) to a coil with four turns will induce in a coil with three turns a changing current with a lower voltage (e.g., 3V of alternating current), given the 6:3 ratio of turns between the primary and secondary windings of the coupled inductors (e.g., coils) in this configuration.

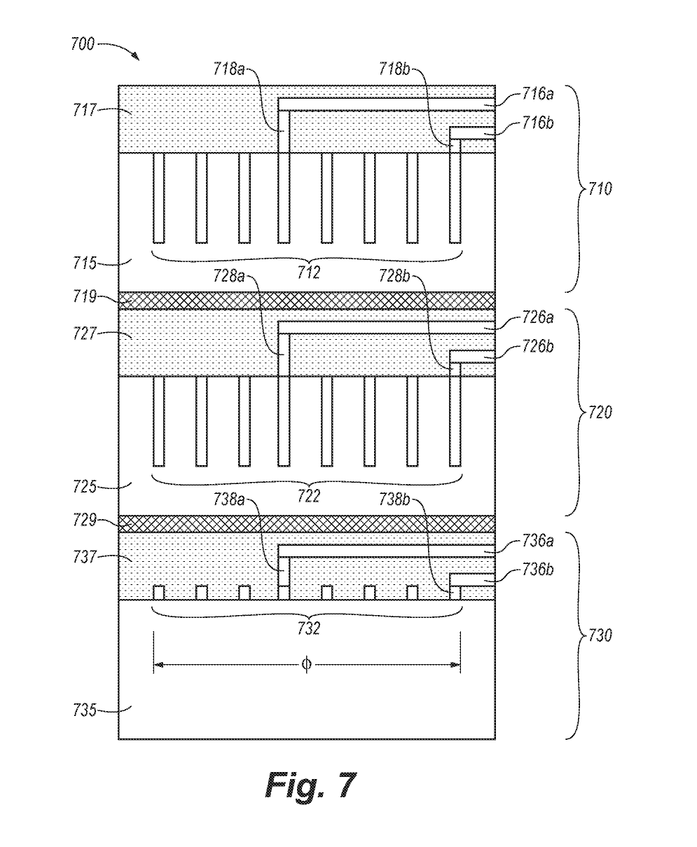

As set forth above, a benefit of providing a semiconductor device with a through-substrate coil for wireless communication is that packages of more than two die can be configured to wirelessly communicate, even when stacked in a front-to-back configuration. For example, FIG. 7 is a simplified cross-sectional view of a multi-die semiconductor device 700 with through-substrate coils in accordance with an embodiment of the present technology. The device 700 includes a first die 710 having a first substrate 715 and a first through-substrate coil 712 (“coil 712”) extending substantially into the substrate 715. The first coil 712 is formed by a conductor (e.g., a plated conductive material filling a substantially spiral-shaped trench) connecting a first end of the first coil 712 to a second end of the first coil 712 along a substantially spiral-shaped path. As can be seen with reference to FIG. 7, the first coil 712 includes about three and one-half turns (e.g., the spiral-shaped path rotates around its central axis through about 1260°). The first coil 712 can be connected to other circuit elements (not shown) in a first layer 717 of insulating material on the front side of the first die 710 by leads 716a and 716b. The leads 716a and 716b can be connected to respective ends of the first coil 712 by two vias 718a and 718b.

The device further includes a second die 720 having a second substrate 725 and a second layer 727 of insulating material on the front side of the second die 720. The second die 720 further includes a second through-substrate coil 722 (“coil 722”) extending substantially into the second substrate 725. The second coil 722 is formed by a conductor (e.g., a plated conductive material filling a substantially spiral-shaped trench) connecting a first end of the second coil 722 to a second end of the second coil 722 along a substantially spiral-shaped path. As can be seen with reference to FIG. 7, the second coil 722 also includes about three and one-half turns (e.g., the spiral-shaped path rotates around its spiral axis through about 1260°). The second coil 722 can be connected to other circuit elements (not shown) in the second layer 727 of insulating material on the front side of the second die 720 by leads 726a and 726b. The leads 726a and 726b are connected to respective ends of the second coil 722 by two vias 728a and 728b.

The device further includes a third die 730 having a substrate 735 and a third layer 737 of insulating material on the front side of the third die 730. The third die 730 further includes a third coil 732 (“coil 732”) disposed in in the upper layer 737 of insulating material over the substrate 735. The third coil 732 is formed by a conductor (e.g., a conductive trace) connecting a first end of the third coil 732 to a second end of the third coil 732 along a substantially spiral-shaped path. As can be seen with reference to FIG. 7, the third coil 732 also includes about three and one-half turns (e.g., the spiral-shaped path rotates around its spiral axis through about 1260°). The third coil 732 can be connected to other circuit elements (not shown) in the upper layer 737 of insulating material on the front side of the third die 730 by leads 736a and 736b. The lead 736a can be connected to the center of the third coil 732 by a via 738a.

The first die 710 and the second die 720 are stacked front-to-back (e.g., the back side of the first die 710 is facing the front side of the second die 720). The second die 720 and the third die 730 are also stacked front-to-back (e.g., the back side of the second die 720 is facing the front side of the third die 730). The device 700 may optionally include a first die attach material 719 (e.g., a die attach film) between the first and second dies 710 and 720, and a second die attach material 729 (e.g., a die attach film) between the second and third dies 720 and 730.

As set forth in greater detail above, closely-spaced coils, such as the first through-substrate coil 712 of the first die 710 and the second through-substrate coil 722 of the second die 720, can be configured to wirelessly communicate over near-field distances (e.g., distances less than about three times the diameter ø of the coils, in which the near-field components of the electric and magnetic fields oscillate). For first and second through-substrate coils 712 and 722 can communicate wirelessly using inductive coupling, in which one of the coils (e.g., the second through-substrate coil 722 of the second die 720) is configured to induce a magnetic field with a flux perpendicular to and passing through both the coils 712 and 722 in response to a current passing through the second through-substrate coil 722 of the second die 720 (e.g., provided by a voltage differential applied across the leads 726a and 726b). By changing the current passing through the second through-substrate coil 722 (e.g., by applying an alternating current, or by repeatedly switching between high and low voltage states), changes can be induced in the magnetic field, which in turn induces a changing current in the first through-substrate coil 712 of the first die 710. In this fashion, signals and/or power can be coupled between a circuit comprising the second through-substrate coil 722 of the second die 720 and another comprising the first through-substrate coil 712 of the first die 710. Similarly, the second through-substrate coil 722 of the second die 720 and the third coil 732 of the third die 730 can be inductively coupled to communicate wirelessly in a similar fashion. Accordingly, signals and/or power provided to the third coil 732 in the third die 730 (e.g., by leads 736a and 736b) can be provided by inductive coupling to the second through-substrate coil 722 in the second die 720, which can in turn provide the signals and/or power by inductive coupling to the first through-substrate coil 712 in the first die 710.

As will be readily understood by one skilled in the art, a coil need not be smoothly spiral shaped (e.g., an Archimedean spiral or an involute circular spiral) to facilitate wireless communication between front- and back-side coil pairs, in accordance with one embodiment of the present technology. Although the coils in the foregoing example Figures have been illustrated schematically and functionally as having smoothly curving arcuate turns of constant curvature, it will be readily understood by those skilled in the art that fabricating a smooth spiral shape can present a costly engineering challenge (e.g., in photolithographic reticle design). Accordingly, a “substantially spiral-shaped” conductor, as used herein, describes a conductor having turns that increase in radial distance outward from a center, whether gradually or in stepped fashion. Accordingly, the planar shape traced out by the path of individual turns of a substantially spiral-shaped conductor need not be elliptical or circular. For the convenience of integration with efficient semiconductor processing methodologies (e.g., masking with cost-effective reticles), individual turns (e.g., including linear elements thereof) of a substantially spiral-shaped conductor can trace out a polygonal path in a planar view (e.g., rectilinear, hexagonal, octagonal, or some other regular or irregular polygonal shape). Accordingly, a “substantially spiral-shaped” conductor, as used herein, describes a planar spiral conductor having turns that trace out any shape in a planar view (e.g., parallel to the plane of the substrate surface) surrounding a central axis, including circles, ellipses, regular polygons, irregular polygons, or some combination thereof.

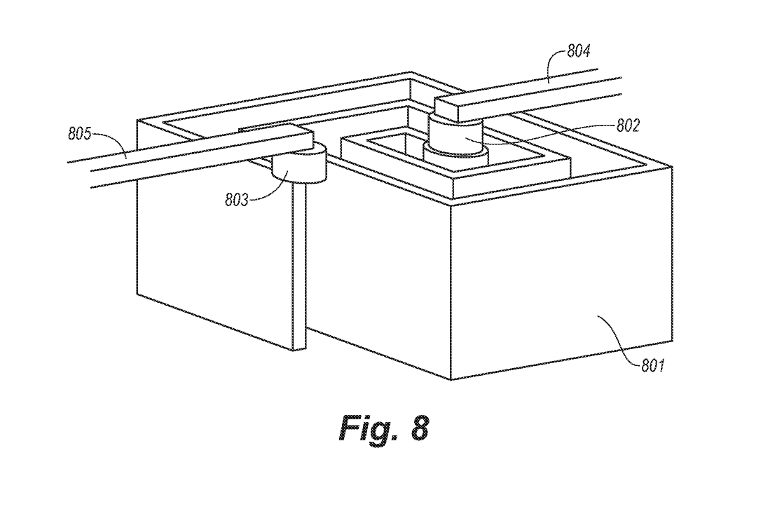

For example, FIG. 8 illustrates a substantially spiral-shaped through-substrate coil 801 with a substantially polygonal spiral shape, in accordance with one embodiment of the present technology. For more easily illustrating the substantially spiral shape of the coil 801 set forth in FIG. 8, the substrate, insulating materials, and other details of the device in which the coil 801 is disposed have been eliminated from the illustration. The coil 801 is connected at its opposite ends to two vias 802 and 803, which in turn connect the coil 801 to two leads 804 and 805. As can be seen with reference to FIG. 8, the substantially spiral-shaped conductor of the coil 801 includes turns with linear elements that increase in distance from a central axis of the coil 801 with each turn.

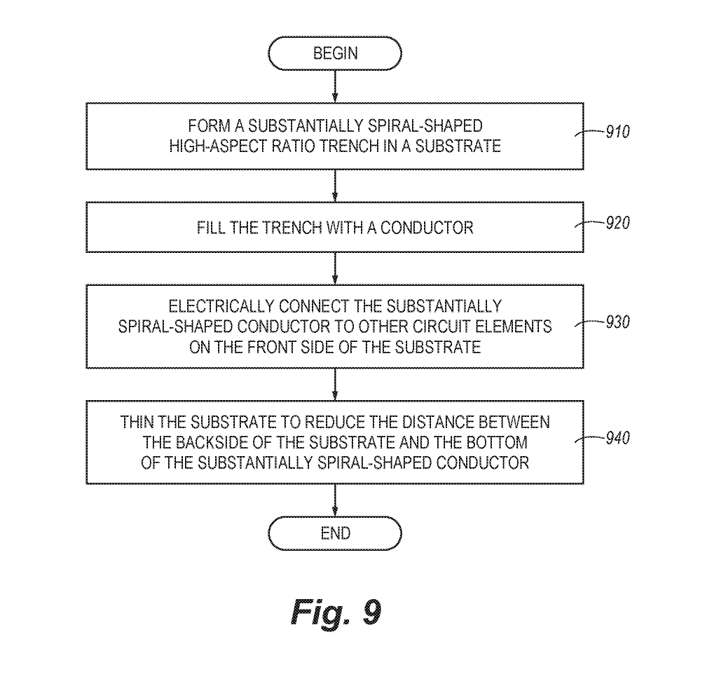

FIG. 9 is a flow chart illustrating a method of manufacturing a semiconductor device with a back-side coil in accordance with an embodiment of the present technology. The method includes forming a substantially spiral-shaped high-aspect ratio trench in a substrate (box 910) and filling the trench with a conductor (box 920). The method further includes electrically connecting the substantially spiral-shaped conductor to other circuit elements on the front side of the substrate (box 930) and thinning the substrate to reduce the distance between the backside of the substrate and the bottom of the substantially spiral-shaped conductor (box 940). The thinning can partially reduce the distance, or completely eliminate the distance (e.g., by partially or fully exposing the bottom of the substantially spiral-shaped conductor).

From the foregoing, it will be appreciated that specific embodiments of the invention have been described herein for purposes of illustration, but that various modifications may be made without deviating from the scope of the invention. Accordingly, the invention is not limited except as by the appended claims.

1. A semiconductor device, comprising:
a substrate having a front side and a back side;
a plurality of circuit elements on the front side of the substrate; and
a spiral-shaped conductor extending downward from the front side of the substrate into the substrate and having a spiral axis perpendicular to the front side of the substrate,
wherein opposite ends of the spiral-shaped conductor are electrically connected to at least one of the plurality of circuit elements.

2. The semiconductor device of claim 1, wherein the spiral-shaped conductor is configured to be wirelessly coupled to another spiral-shaped conductor in another semiconductor device.

3. The semiconductor device of claim 1, further comprising a layer of insulating material covering the spiral-shaped conductor.

4. The semiconductor device of claim 1, wherein the substrate has a thickness, and wherein the substantially spiral-shaped conductor extends into the substrate by at least half of the thickness.

5. The semiconductor device of claim 1, wherein the spiral-shaped conductor extends completely through the substrate.

6. The semiconductor device of claim 1, wherein the substrate is a silicon substrate between 10 μm and 200 μm thick, and wherein the spiral-shaped conductor extends into the substrate by at least 30 μm.

7. The semiconductor device of claim 1, wherein the spiral-shaped conductor spans an area of between 80 μm and 600 μm across.

8. The semiconductor device of claim 1, wherein turns of the spiral-shaped conductor each have a width of between about 15 μm and 75 μm across.

9. (canceled)

10. A semiconductor package, comprising:
a first die including:
a first substrate having a front side and a back side,
a first plurality of circuit elements on the front side of the first substrate, and
a first spiral-shaped conductor extending downward from the front side of the first substrate into the first substrate and having a spiral axis perpendicular to the front side of the first substrate; and
a second die including:
a second substrate having a front side and a back side,
a second plurality of circuit elements on the front side of the second substrate, and
a second spiral-shaped conductor,
wherein the first spirally-shaped conductor and the second spirally-shaped conductor are wirelessly coupled.

11. The semiconductor package of claim 10, wherein the first spirally-shaped conductor and the second substantially spiral-shaped conductors conductor are configured to wirelessly communicate by inductive coupling.

12. The semiconductor package of claim 10, wherein the first spirally-shaped conductor and the second spiral-shaped conductor are configured to wirelessly communicate by capacitive coupling.

13. The semiconductor package of claim 10, wherein each of the first spirally-shaped conductor and the second spiral-shaped conductor has a span of between 80 μm and 600 μm across.

14. The semiconductor package of claim 10, wherein the first spirally-shaped conductor and the second spiral-shaped conductors conductor are coaxially aligned.

15. The semiconductor package of claim 10, wherein the first substrate has a thickness, and wherein the first spiral-shaped conductor extends into the substrate by at least half of the thickness.

16. The semiconductor package of claim 10, wherein the first spiral-shaped conductor extends completely through the first substrate.

17. The semiconductor package of claim 10, wherein the second spiral-shaped conductor extends downward from the front side of the second substrate into the second substrate.

18. The semiconductor package of claim 10, wherein the first die and the second die are stacked in a front-to-back arrangement.

19. A semiconductor package, comprising:
a plurality of dies arranged in a stack, each die including a substrate, a plurality of circuit elements on a front side of the substrate, and a spiral-shaped conductor having a spiral axis perpendicular to a surface of the substrate,
wherein adjacent dies of the plurality of dies are wirelessly coupled by the respective spiral-shaped conductors thereof, and
wherein the spiral-shaped conductor of a first die of the plurality of dies extends downward from the front side of the substrate of the first die into the substrate thereof of the first die.

20. The semiconductor package of claim 19, wherein the plurality of dies includes more than two dies.
